(19) United States
(12) Patent Application Publication
(10) Pub. No.: US 2011/0041899 A1
(43) Pub. Date: Feb. 24, 2011

(54) Three Dimensionally Structured Thin Film Photovoltaic Devices with Self-Aligned Back Contacts

(75) Inventors: Daniel Josell, North Potomac, MD (US); Carlos R. Beauchamp, Jefferson, MD (US); Thomas P. Moffat, Gaithersburg, MD (US)

Correspondence Address: DAPHNE BURTON, 2029 CENTURY PARK EAST, SUITE 1400, LOS ANGELES, CA, 90067, US

(73) Assignee: National Institute of Standards and Technology, Galthersburg, MD (US)

(21) Appl. No.: 12/609,699

(22) Filed: Oct. 30, 2009

(51) Int. Cl. H01L 31/0224; H01L 31/06; H01L 31/18

(52) U.S. Cl. 136/255; 438/95; 257/E31.124

(57) ABSTRACT

A process for producing three dimensionally structured thin film photovoltaic devices with self-aligned back contacts. The photovoltaic device is constructed using electrodeposition on micrometer-scale interdigitated electrodes on an insulating substrate. During fabrication, these interdigitated electrodes serve as the active electrodes for deposition of materials including semiconductors. After fabrication, these interdigitated electrodes serve as back contacts for carrier collection when the device is in use. The process can be used to fabricate homojunction, heterojunction and multijunction photovoltaic devices.

### STATEMENT REGARDING FEDERALLY SPONSORED RESEARCH/DEVELOPMENT

The subject matter of this patent application was invented by employees of the United States Government. Accordingly, the United States Government may manufacture and use the invention for governmental purposes without the payment of any royalties.

### BACKGROUND OF THE INVENTION

1. Field of Invention

The present disclosure relates to photovoltaic devices and, more particularly, to photovoltaic devices produced by an electrochemical deposition process onto two or more electrodes, each including a contact pad and a number of parallel wires connected to the contact pad, the wires of the different electrodes being interdigitated.

2. Description of Related Art

Photovoltaic or solar devices may be used to convert light directly into electrical current. This conversion may be accomplished via the conjunction of n-type and p-type semiconducting materials that separate electron-hole pairs which are created when light is absorbed by the photovoltaic device.

Three generations of photovoltaic devices currently exist. First generation photovoltaic devices may have thicknesses in a range of from about one hundred (100) micrometers to hundreds (100s) of micrometers. First generation devices are generally thicker than subsequent generations because they are generally based on silicon, and the indirect bandgap of silicon may require thicknesses within this range for the effective capture of light. If these devices were much thinner, much of the light might simply pass through the device instead of being absorbed by the silicon material.

Second generation devices may incorporate thin films of direct bandgap semiconducting materials. Such materials may include cadmium telluride or copper indium gallium diselenide for the p-type material. This p-type material may be classified as an absorber and may constitute the majority of the photovoltaic device. Lower costs may be possible using thin films since thin film materials may be deposited using a variety of techniques and less material is required to effectively absorb incident light. On the other hand, decreased efficiency in light conversion may result when thin film devices are compared to crystalline silicon devices.

Third generation devices may include three-dimensional (3D) micro- or nano-scale structures (e.g., nano-wires and nano-rods in polymers) to improve their efficiency. Use of such third-generation devices is predicated on their having an even lower cost than second generation devices and/or higher efficiency.

In connection with the development of second and third generation photovoltaic devices, various geometries are either being used or considered. Such geometries may include a geometry pursuant to which electrical contacts for extracting charge carriers (holes and electrons) are located on opposing surfaces of the thin film.

In some cases, third generation devices may contain nanoparticles that are dispersed during fabrication, as opposed to being grown on the substrate of the device itself. A drawback to this dispersed configuration exists in that it may be a challenge to ensure uninterrupted connectivity of all constituent regions to an electrode. It may also be a challenge to connect said nanoparticles to the correct electrode.

These second and third generation geometries may have drawbacks in that the electrode on the side of the photovoltaic device that faces the sun may block some of the incoming light, thus adversely affecting the photovoltaic device's performance while also increasing its cost and processing complexity.

Advances have been made to address shortcomings associated with the blockage of incoming light caused by the front contacts (on the surface that faces the sun) in first generation devices. Devices that use interdigitated contacts on the back surface (surface not facing the sun) may eliminate light blockage caused by the front contacts. Silicon-based devices have been explored for more than thirty years. Such devices can use line or point contacts created through multiple lithographic patterning (masking) and deposition steps to create localized doping on the back surface of silicon wafers. The doped regions connect to metal busbars also located on the back surface for extraction of electrical current.

Sequential masking steps may also be used to create two interleaved arrays of n-type and p-type doped spots (point contacts) on the back surface of a silicon wafer, which may minimize recombination on the area that interfaces between metal and semiconductor.

Such back surface interdigitated contacts on silicon wafers may be optimized by spacing the lines on which the doped regions fall to a distance on the order of 50 micrometers to 100 micrometers, which is similar to the silicon semiconductor thickness. This length scale may be beneficial in light of sequential masking steps required to create interleaved doping and structures.

Analogous back-contact geometries for thin film devices with micrometer-scale thickness may require a contact (electrode) pitch that is at or below a few micrometers. Accordingly, a process that self-aligns the wires of the electrodes, e.g., by fabricating them simultaneously in a single lithographic patterning, may be preferable to one that requires multiple lithographic patternings. For example, a process has been described for silicon-based devices that uses localized etch-back through the n-region to the p-region and subsequent metal deposition onto both the remaining n-surface and the exposed p-surface with dimensions of tens and hundreds of micrometers. This process relies on controlled undercutting of the etched semiconductor to avoid shorting of metal depositing on the upper n-type surface and the recessed p-type surface. Accordingly, this process may be more difficult to implement on a large scale with thin film devices.

There is a need for thin film photovoltaic devices that incorporate back contacts and that eliminate the blockage of incoming light caused by the front contacts.

There is further need for photovoltaic devices with back contacts that can be fabricated with reduced costs when compared to those requiring multiple lithographic patternings.

### BRIEF SUMMARY OF DISCLOSURE

The present disclosure addresses the foregoing deficiencies of the prior art by providing a three-dimensional thin film photovoltaic device with self-aligned back contacts that are used for carrier collection when the device is illuminated. The back contacts are interdigitated electrodes that are also used for fabrication of the device.

In accordance with one embodiment of the present disclosure, an electrodeposition method is provided for forming three dimensionally structured thin film photovoltaic devices. The method comprises the steps of providing at least two interdigitated electrodes on an insulating substrate, each of the at least two interdigitated electrodes including a plurality of interdigitated wires having pitches of less than ten micrometers. In a first step, the method comprises electrodepositing one or more thin films of one or more of a first semiconducting material onto a first interdigitated electrode, wherein the first semiconducting material is one of an n-type or p-type material. In a second step, the method comprises depositing one or more thin films of one or more of a second semiconducting material onto at least a second interdigitated electrode until the deposits on the first interdigitated electrode and the second interdigitated electrode impinge upon each other, wherein the second semiconducting material is the other of an n-type or p-type material. After fabrication of the photovoltaic device, at least two of said at least two interdigitated electrodes serve as the back contacts for carrier extraction when the device is in use.

In accordance with another embodiment of the present disclosure, an electrodeposition method is provided for forming a multijunction three dimensionally structured thin film photovoltaic device with self-aligned back contacts. The method for forming a multijunction device comprises providing at least two interdigitated electrodes on an insulating substrate, each of the at least two interdigitated electrodes including a plurality of interdigitated wires having pitches of less than ten micrometers, wherein the at least two interdigitated electrodes include a first interdigitated electrode and a second electrode. In a first step, the method comprises electrodepositing one or more thin films of one or more of a first semiconducting material onto the first interdigitated electrode without impingement upon any other of the at least two interdigitated electrode, the first semiconducting material being one of an n-type or p-type material.

In a second step, the method for forming a multijunction device comprises electrodepositing one or more thin films of one or more of a second semiconducting material onto at least said first interdigitated electrode but without impinging upon said second interdigitated electrode, the second semiconducting material being the other type of an n-type or p-type material. In a third step, the method comprises electrodepositing one or more thin films of one or more of a third semiconducting material onto either the first or second interdigitated electrode without impinging on the other of the first or second interdigitated electrode, the third semiconducting material being either the same type as the first semiconducting material if electrodeposited on the first interdigitated electrode, or the same type as the second semiconducting material if electrodeposited on the second interdigitated electrode, wherein the third semiconducting material is either an n-type or p-type material.

In a fourth step, the method for forming a multijunction device comprises depositing one or more thin films of one or more of a fourth semiconducting material onto one or more of the at least two interdigitated electrodes, wherein the depositing occurs at least until the thin films on the first interdigitated electrode and the second interdigitated electrodes impinge upon each other, wherein the fourth semiconducting material is the other of said either an n-type or p-type material electrodeposited in the third step. After fabrication of the multijunction photovoltaic device, at least two of said at least two interdigitated electrodes serve as the back contacts for carrier extraction when the device is in use.

In accordance with yet another embodiment of the present disclosure, a three dimensionally structured thin film photovoltaic device is provided with self-aligned back contacts that are formed by electrodeposition on interdigitated electrodes used in the device's manufacture. The device comprises an insulating substrate, and at least two interdigitated electrodes on the insulating substrate, the at least two interdigitated electrodes including a plurality of interdigitated wires having pitches of less than ten micrometers, wherein the at least two interdigitated electrodes include a first interdigitated electrode and a second interdigitated electrode. The device also comprises one or more electrodeposited thin film layers of one or more of a first semiconducting material on the first interdigitated electrode, wherein the first semiconducting material is either an n-type or p-type material. The device further comprises one or more deposited thin film layers of one or more of a second semiconducting material on the second interdigitated electrode, wherein the deposits on the first interdigitated electrode and the second interdigitated electrode impinge upon each other, wherein the second semiconducting material is the other of an n-type or p-type material. After fabrication, at least two of said at least two interdigitated electrodes are configured to serve as the back contacts for carrier extraction, when the device is in use.

In accordance with still another embodiment of the present disclosure, a three dimensionally structured thin film multijunction photovoltaic device is provided with self-aligned back contacts that are formed by electrodeposition on interdigitated electrodes used in the device's manufacture. The multijunction device comprises an insulating substrate, and at least two interdigitated electrodes on the insulating substrate, the at least two interdigitated electrodes including a plurality of interdigitated wires having pitches of less than ten micrometers. The at least two interdigitated electrodes include a first interdigitated electrode and a second interdigitated electrode. The device also comprises one or more electrodeposited thin film layers of one or more of a first semiconducting material on the first interdigitated electrode without impingement upon any of the other interdigitated electrodes, wherein the first semiconducting material is one of an n-type or p-type material.

The multijunction device also comprises one or more electrodeposited thin film layers of one or more of a second semiconducting material on at least said first interdigitated electrode but without impinging upon the second interdigitated electrode, wherein the second semiconducting material is the other of an n-type or p-type material. The multijunction device further comprises one or more electrodeposited thin film layers of one or more of a third semiconducting material on either the first or second interdigitated electrode without impinging upon the first and second interdigitated electrodes, the third type being either the same type as the first type if electrodeposited on the first interdigitated electrode or the same type as the second type if electrodeposited on the second interdigitated electrode, wherein the third semiconducting material is either an n-type material or a p-type material.

The multijunction device still further comprises one or more deposited layers of one or more of a fourth semiconducting material on one or more of the interdigitated electrodes such that the deposits on at least the first interdigitated electrode and the second interdigitated electrodes impinge upon each other, and wherein the fourth semiconducting material is the other of said either an n-type or p-type material as the third semiconducting material. After fabrication, at least two of said at least two interdigitated electrodes are configured to serve as the back contacts for carrier extraction when the device is in use.

These, as well as other objects, features and benefits will now become clear from a review of the following detailed description of illustrative embodiments and the accompanying drawings.

### BRIEF DESCRIPTION OF DRAWINGS

FIG. 1 is an interdigitated electrode structure with two interdigitated electrodes each containing a rectangular contact pad region and a number of electrode wires (lines) extending from that pad toward the other pad in accordance with one embodiment of the present disclosure.

FIG. 2 is an illustration of a cross-sectional view of two adjacent interdigitated electrode wires from the interdigitated electrode device of FIG. 1 during semiconductor deposition in accordance with one embodiment of the present disclosure.

FIG. 3A is a deposition cell in accordance with one embodiment of the present disclosure.

FIG. 3B is an exploded view of a substrate viewed from the side with electrodes on the bottom of the substrate, where the substrate is coupled to contacts so that electrodeposition may be controlled independently on the two electrodes on said substrate in accordance with one embodiment of the present disclosure.

FIG. 4 is a graphical illustration of the current recorded over time during deposition at different deposition potentials on planar substrates in an electrolyte in accordance with one embodiment of the present disclosure.

FIG. 5A is an interdigitated electrode structure for a multijunction device with two interdigitated electrodes each containing a rectangular contact pad region and a number of electrode wires (lines) extending from that pad toward the other pad in accordance with one embodiment of the present disclosure.

FIG. 5B is an illustration of a cross-sectional view of four adjacent interdigitated electrode wires from the interdigitated electrode device of FIG. 5A during semiconductor deposition of a multijunction photovoltaic device in accordance with one embodiment of the present disclosure.

FIG. 5C is another embodiment of a cross-sectional view of four adjacent interdigitated electrode wires from an interdigitated electrode device such as that of FIG. 5A, during semiconductor deposition of a multijunction photovoltaic device in accordance with one embodiment of the present disclosure.

FIG. 5D is an interdigitated electrode structure for a multijunction device with four interdigitated electrodes each containing a rectangular contact pad region and a number of electrode wires (lines) extending from that pad toward the other pad in accordance with one embodiment of the present disclosure.

FIG. 5E is a cross-sectional view of an interdigitated electrode structure for a multijunction device with four interdigitated electrodes during semiconductor deposition in accordance with one embodiment of the present disclosure.

FIG. 6A is an illustration of interdigitated electrodes after deposition on one electrode, and a corresponding cross-sectional view showing the structure of n-type material surrounded by p-type material formed by a transition from n-type to p-type material during electrodeposition in accordance with one embodiment of the present disclosure.

FIG. 6B is a graphical illustration of the current histories recorded during deposition on the electrodes of FIG. 6A.

FIG. 7A (upper image) is a cross-section view of a substrate with contacts and n-type and p-type semiconductor deposited through impingement to form a photovoltaic device in accordance with one embodiment of the present disclosure, and (lower image) a cross-section view of a device with higher aspect ratio contacts and a more complex geometry including n+ and p+ semiconductor layers to improve performance.

FIG. 7B is a graphical illustration of the voltage histories applied to the two electrodes and the sum of the currents recorded during semiconductor deposition on the two electrodes of a cadmium telluride (CdTe) homojunction photovoltaic device such as pictured in FIG. 7A in accordance with one embodiment of the present disclosure.

FIG. 7C is a graphical illustration of the voltage histories applied to the two electrodes, the currents recorded during semiconductor deposition on the two electrodes and the sum of those current histories during fabrication of a CdTe homojunction photovoltaic device such as pictured in FIG. 7A in accordance with one embodiment of the present disclosure.

FIG. 8A is a graphical illustration of the real and imaginary parts of the dielectric function ∈ for cadmium telluride deposited on planar substrates in both the as-deposited and annealed states in accordance with one embodiment of the present disclosure.

FIG. 8B is a graphical illustration of the derived absorption coefficient for as-deposited and annealed CdTe in accordance with one embodiment of the present disclosure.

FIG. 9 is a graphical illustration of X-ray diffraction results for as-deposited and annealed CdTe on planar substrates in accordance with one embodiment of the present disclosure.

FIG. 10 is a graphical illustration of the External Quantum Efficiency (EQE), a measure of the efficiency of the conversion of light energy to electrical energy, as a function of the wavelength of the incoming light for as-deposited devices with different geometries and materials in accordance with one embodiment of the present disclosure.

### DETAILED DESCRIPTION OF THE DISCLOSURE

The present disclosure is directed to three dimensionally structured thin film photovoltaic devices with self-aligned back contacts. Fabrication of this photovoltaic device includes an electrodeposition process on at least one of two or more interdigitated electrodes.

The electrodeposition process described herein applies to existing technologies for production of interdigitated electrodes to create a new and unobvious self-aligned electrochemical deposition process.

Interdigitated damascene wires with a pitch below 100 nanometers (nm) are regularly fabricated in interdigitated comb-like electrode structures to study leakage current in microelectronics applications. It is also known to deposit micrometer pitch interdigitated electrodes on top of semiconductors to form metal-semiconductor-metal structures for photodetectors. However, in accordance with the present disclosure, such patterned electrically conducting wires on an insulating substrate may serve as the active electrodes for electrodeposition of zero or more metals on one or more electrodes and electrodeposition of one or more semiconductors on one or more electrodes for fabrication of the device. After fabrication and when the device is in use, these same electrodes can serve as the back contacts for carrier collection.

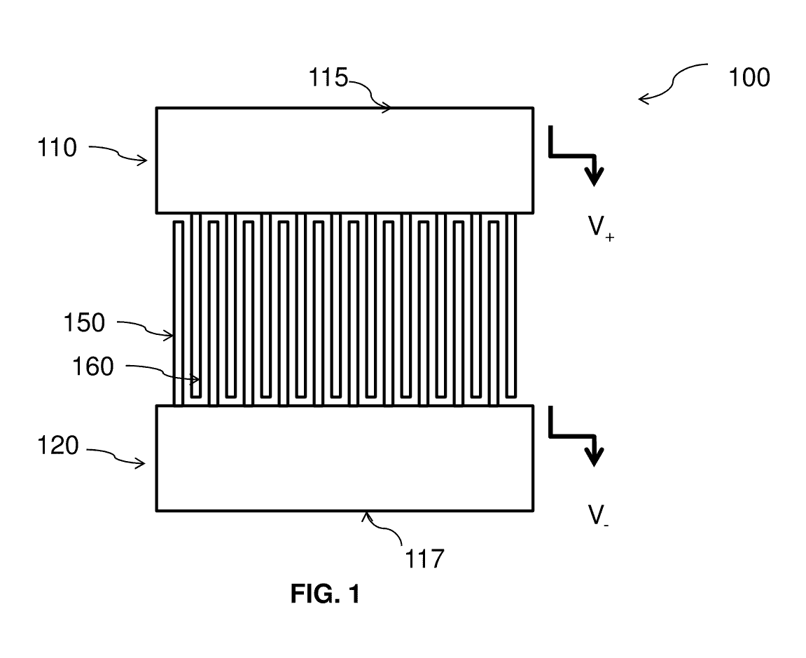

Referring now to FIG. 1, illustrated is an interdigitated electrode structure 100 in accordance with one embodiment of the present disclosure. As shown in FIG. 1, a group of parallel wires, including wire 160, are attached to each other by a contact pad 115, thus forming a first interdigitated electrode 110. A second group of parallel wires, including wire 150, are attached to each other by a second contact pad 117, thus forming a second interdigitated electrode 120. For purposes of the present disclosure, the two groups of contact pads and wires together may be referred to as interdigitated electrodes because the geometry in FIG. 1 interleaves the electrically connected wires from each of the two electrodes. Because all wires on each electrode are electrically connected through their respective contact pads 115, 117, this diagram of FIG. 1 may also be said to contain two electrodes 110, 120.

For purposes of the present disclosure, pitch is defined as the distance between the centers of two adjacent interdigitated wires. For example, in FIG. 1, pitch could be defined as the distance between the first wire 160 (positive) and a second wire 150 (negative.) For purposes of the present disclosure, the pitch may range from tens of nanometers to tens of micrometers. While the pitch will be tens of micrometers or smaller, the length of these wires is not constrained and may be relatively much longer, e.g., several millimeters or centimeters long.

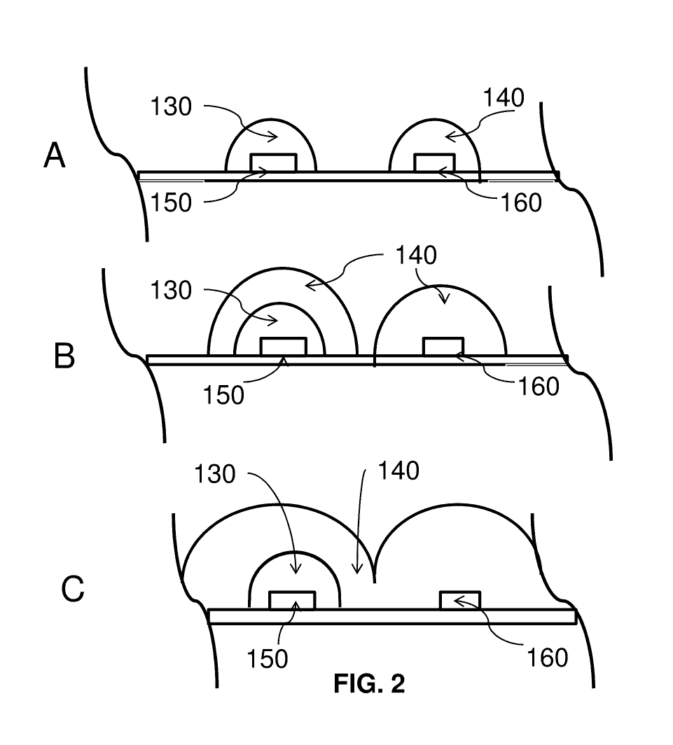

Referring now to FIG. 2, illustrated are two adjacent wires from the interdigitated electrode structure of FIG. 1 in an electrodeposition process in accordance with one embodiment of the present disclosure. The electrodeposition process is shown at three different points in time, with diagram A of FIG. 2 being the earliest in time, diagram B being later in time than diagram A, and diagram C being latest in time.

As shown in diagram A of FIG. 2, the electrodeposition process may be adapted to first produce an n-type material 130 around one electrode 120, including wire 150 and all wires connected to the contact pad for this electrode 120. A p-type material 140 may be electrodeposited onto a second electrode 110 (including wire 160 and all wires connected to the same contact pad for this electrode 110) either concurrently or subsequently in the same electrolyte or subsequently in a different electrolyte. As shown in diagram B of FIG. 2, a p-type material 140 can be deposited onto both electrodes 110, 120 sequentially or simultaneously. In diagram C of FIG. 2, the p-type material 140 may be deposited over both electrodes 110, 120 until a continuous thin film is formed by the deposits on the two electrodes 110, 120. After the materials around the electrodes 110, 120 impinge upon each other as shown in Diagram C, p-type material may still be deposited to obtain thicker deposits.

The electrodeposition process may be adapted to produce a structure in which n-type and p-type materials in the immediately preceding paragraph are reversed, i.e., n-type is replaced by p-type and p-type is replaced by n-type. The electrodeposition process described in connection with FIG. 2 may be conducted within a single electrolyte to form a homojunction device (n-type and p-type semiconductors are of the same material). Alternatively, the process may be conducted in one or more electrolytes to form a heterojunction device (i.e., n-type and p-type semiconductors are of two or more different semiconductor materials), or to gain further control of materials deposited, dopant concentrations and photovoltaic device performance. Cadmium telluride is an example of the material that may be deposited. Alternatively, any other deposition material may be used that is suitable for the photovoltaic device being manufactured. Other suitable materials may include, without limitation, copper indium gallium diselenide, copper oxide and cadmium sulfide. It should be noted that the term electrodeposition may be used interchangeably with electroplating.

CdTe may be electrodeposited using a codeposition technique, resulting in near-stoichiometric CdTe. This CdTe deposition process may incorporate use of an electrolyte that is relatively concentrated in cadmium (Cd) and dilute in telluride (Te).

A deposition potential may be selected so that elemental Te deposits from a solution that has only Te salts, but elemental Cd does not deposit from a solution having only Cd salts. A range of deposition potentials is available so that whenever a Te atom deposits a Cd atom reacts with it as a result of the enthalpy of reaction of Cd and Te, thus creating a CdTe deposit. By using Te that is relatively dilute when compared to Cd, a well controlled composition can result.

Electrodeposition may be accomplished in a primary aqueous electrolyte, with constituents including the metal salt of the metal to be deposited. A primary electrolyte for the present electrodeposition process may have a concentration of 0.1 mol/L Cd⁺², which may be found by adding 3(CdSO₄).8H₂O salts (99.999% by mass) to 18 megaohms (MΩ)cm water. The primary electrolyte may also be saturated with Te⁻⁴ by adding TeO₂ (99.999% by mass) until a surplus of oxide powder is visible at the bottom of the deposition cell. The resulting electrolyte may contain about 0.1 mmol/L Te⁻⁴ based on the tellurium Pourbaix diagram and solution pH of 2.0, acquired by adding sulfuric acid.

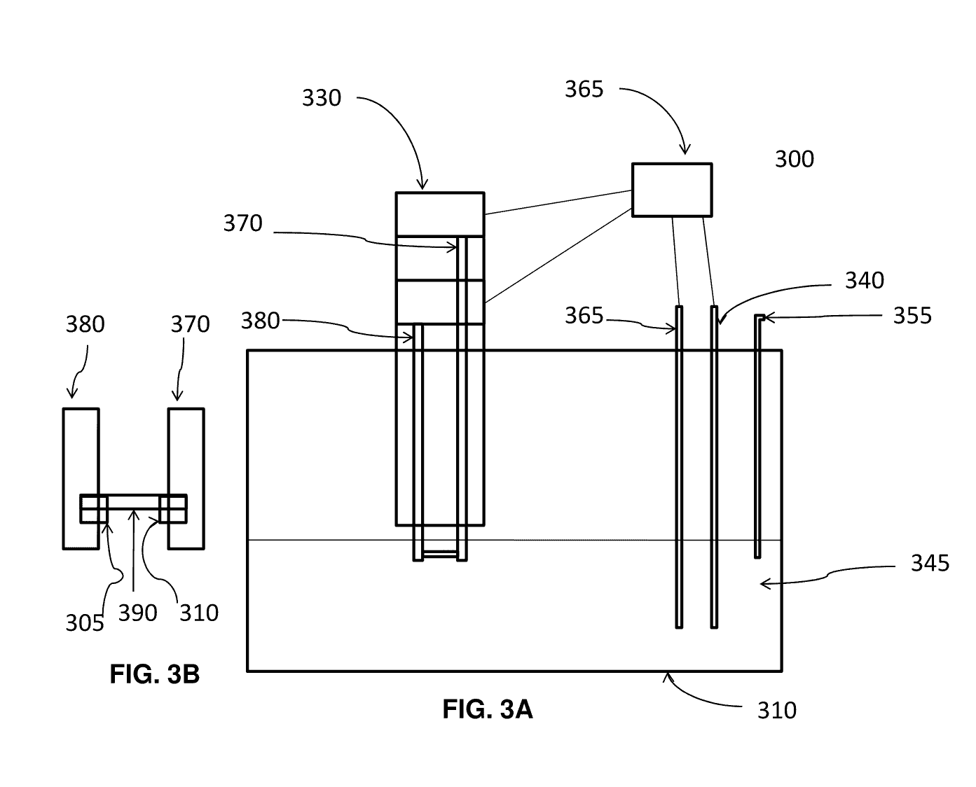

Referring now to FIG. 3A, illustrated is a deposition cell in accordance with one embodiment of the present disclosure. The deposition cell 300 may have a receptacle 310 that is configured to hold 100 mL of solution, e.g., electrolyte 345, which is the primary electrolyte described immediately hereinabove. The deposition cell 300 may also include a platinum counter electrode 340, and a mercury/mercurous-sulfate reference electrode 365 in saturated potassium sulfate (behind a glass frit so that the primary electrolyte and potassium sulfate do not substantially mix) that enables definition of applied deposition potentials during the electrodeposition of materials. Potentials defined in this way will be referred to as Vss. Also included within the deposition cell 300 may be an ultra-high purity argon gas sparge line 355 that may run continuously during and between depositions to remove dissolved oxygen. The cell 300 may have one or more ports for a rotating substrate holder 330, which may act as a cathode for deposition.

Referring now to FIG. 3B, illustrated is an exploded side view of a substrate 390 showing how the contact pads for the electrodes 310, 305, on substrate 390 may be electrically coupled to contacts 370, 380, respectively, so that electrodeposition may occur onto substrate 390. All potentials that result may be relative to the saturated sulfate reference electrode (Vss) and a convention of positive current representing CdTe deposition may be used. In other words, reduction processes may be declared as positive currents.

Substrate 390 may be a planar or patterned substrate. If a planar substrate is used, any material suitable for the intended photovoltaic device may be used. For example, metal-coated oxidized silicon wafers may be used for the CdTe deposition process. Substrates with evaporated gold and iridium coatings may be used as well, and may include an underlying titanium adhesion layer.

Substrate 390 is made of an electrically insulating material, e.g., glass, one or more polymers, silicon wafers with an oxidized surface, or metal foil coated with an insulating layer. If substrate 390 is a patterned substrate, any insulating material suitable for the intended photovoltaic device may be used. For example, the patterned substrate may be obtained from thermally oxidized silicon wafers that were lithographically patterned with arrays of interdigitated electrodes. The electrodes may be gold or platinum, and may have heights in the range of 25 nm to 150 nm, with a 5 nm titanium adhesion layer. The area containing the interdigitated wires may be 5 mm by 5 mm, with their metal lines being 5 mm long and adjacent lines being alternately connected to one of two planar contact areas (contact pads).

Any array geometry suitable for the intended photovoltaic device may be used. For example, the array geometries may be classified as fine or intermediate. The fine pitch may have, e.g., 1.3 micrometer wide lines with 0.7 micrometer wide spaces between the lines. In other words, there may be a 2 micrometer pitch between adjacent lines and 4 micrometer pitch between the closest lines on the same electrode. The intermediate pitch may have 1.5 micrometer wide lines with 2.5 μm wide spaces between adjacent lines. As per the example, the pitch may be greater, or less than, twice the wire width.

In the case of either planar or patterned substrates, electroplaters tape may be used to mask the surface of substrate 390 while electrodeposition occurs. This masking may restrict the region over which deposition could occur on electrodes 305 and 310. Separate electrical connections may be made to the two interdigitated electrodes for patterned substrates. Their potentials may be independently controlled and associated deposition currents may be separately measured. Referring back to FIG. 3A, illustrated is a bipotentiostat 365 that may be used to independently control the potentials or deposition currents on the two interdigitated electrodes of FIG. 3B.

Thin films material may be electrodeposited onto substrate 390 using the custom-made rotating electrode 330 that holds individual specimens, each substrate 390 being approximately 8 mm to 11 mm on a side. The substrates may be planar and unpatterned or, alternatively, patterned. For purposes of the present disclosure, thin film deposition describes a technique pursuant to which a film is deposited which has a thickness in the range of about 1 nm to tens (10s) of micrometers. Such thin film techniques are known in the art.

Depositions may be conducted with the substrate 390 rotating at 60 revolutions per minute (rpm) to define hydrodynamics. The electrolyte temperature may be held at 50° C. to 90° C. Substrate 390 may be inserted into the electrolyte with a droplet of 18 MΩcm water on the surfaces of substrate 390 to reduce the risk of contamination during immersion through the electrolyte/air interface. Potentials may be applied after several seconds of rotation to allow the resistive water to be displaced from the substrate prior to deposition.

For deposition on planar substrates, the impact of potential on the electrical properties of electrodeposited CdTe has been noted previously. That is, n-type material may be deposited at more negative potentials (nearer the reversible potential for Cd electrodeposition, i.e., the highest potential for which Cd electrodeposits in the particular electrolyte and conditions) and p-type material may be deposited at more positive potentials (nearer the reversible potential for Te electrodeposition).

It is significant that deposition characteristics are potential dependent. Also as-deposited n-type CdTe materials type-convert to p-type CdTe after annealing. Moreover, devices using CdTe materials deposited at more positive potentials may exhibit lower quantum efficiencies. It should also be noted that low concentrations of elements such as copper or indium can be added to the electrolyte to create doped CdTe semiconductors.

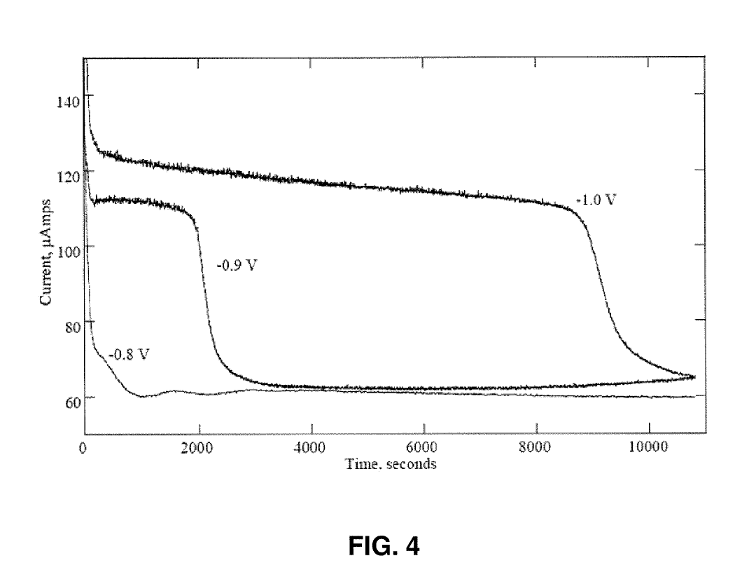

Referring now to FIG. 4, illustrated is a graphical representation of the current over time recorded during deposition on planar substrates in the primary electrolyte in accordance with one embodiment of the present disclosure. The potential as well as time dependence of the deposition can be seen in FIG. 4, which shows the deposition current histories observed at different potentials. Deposition was conducted in the primary electrolyte with an addition of an indium (In) dopant on substrates masked with electroplaters tape to expose a circular area of 0.5 cm². More particularly, the dopant may be 0.3 μmol/L In⁻³ dopant (from In₂S0₄). The data at −1.0V (V is Vss in this figure) and −0.8 V may be taken on planar iridium (Ir) while the data at −0.9 V may be taken on planar gold (Au). Date taken at −0.9 V on planar Ir appear to be consistent with the data on Au. The deposition current observed at −1.0 V is initially higher than the current observed at −0.8 V. Based on studies using similar, dopant-free electrolytes, the current-decrease observed during the −1.0 V and −0.9 V depositions reflects a change in the nature of the material deposited (transitioning from n-type to p-type). The persistence of the higher current over a longer period at the more negative electrode potential is consistent with this explanation.

For patterned substrates, depositions on patterned substrates may be conducted using In-doped electrolyte of nominal concentration 0.4 μmol/L In⁻³. Indium may create n-type CdTe if it displaces Cd on a Cd sublattice site. It is also possible that Indium can be added to other acid electrolytes to create In-doped CdTe.

Photovoltaic devices require differentiation of the two or more interdigitated electrodes in order to separate electron/hole pairs formed by absorption of light. If the CdTe type varies in a step-wise fashion from p→n with increasing potential, then this differentiation can be accomplished through the application of different potentials to the interdigitated electrodes during electrodeposition to surround one electrode with n-type material and the other with p-type semiconductor. Formation of such internal homojunctions during CdTe electrodeposition has been explored extensively in planar geometries. If the type varies from p⁺⁺→p⁺→p→n→n⁺→n⁺⁺ with increasing potential then systematic variation of the potentials on the two electrodes can create more complex structures. The n-type and p-type materials can be deposited simultaneously from a single electrolyte by applying appropriate potential histories to the two electrodes. If deposition on both electrodes can be controlled arbitrarily then depositions can also be carried out sequentially in two or more separate electrolytes.

The process for electrodeposition on interdigitated electrodes may also be used for heterojunction devices. The heterojunction device creation process could be a two-step process that deposits two dissimilar or different semiconducting materials, e.g., CdS and CdTe. For purposes of the present disclosure, dissimilar or different materials are those having different chemical compositions. However, materials such as n-type CdTe and p-type CdTe are not considered dissimilar or different. Fabrication of heterojunction devices could require a variation on the process disclosed for homojunction devices. More particularly, n-type CdS could be electrodeposited on one electrode in one electrolyte. P-type CdTe could then be deposited on one or both electrodes in a second electrolyte or uniformly across the entire specimen surface including on both electrodes through any thin film deposition process including, but not limited to sputter deposition, close-cell sublimation, evaporation or chemical vapor deposition.

Point contacts, rather than line contacts may also be accessible with additional lithography prior to electrodeposition of the photovoltaic materials, e.g., by masking the electrodes with insulating lines orthogonal to the metallization lines.

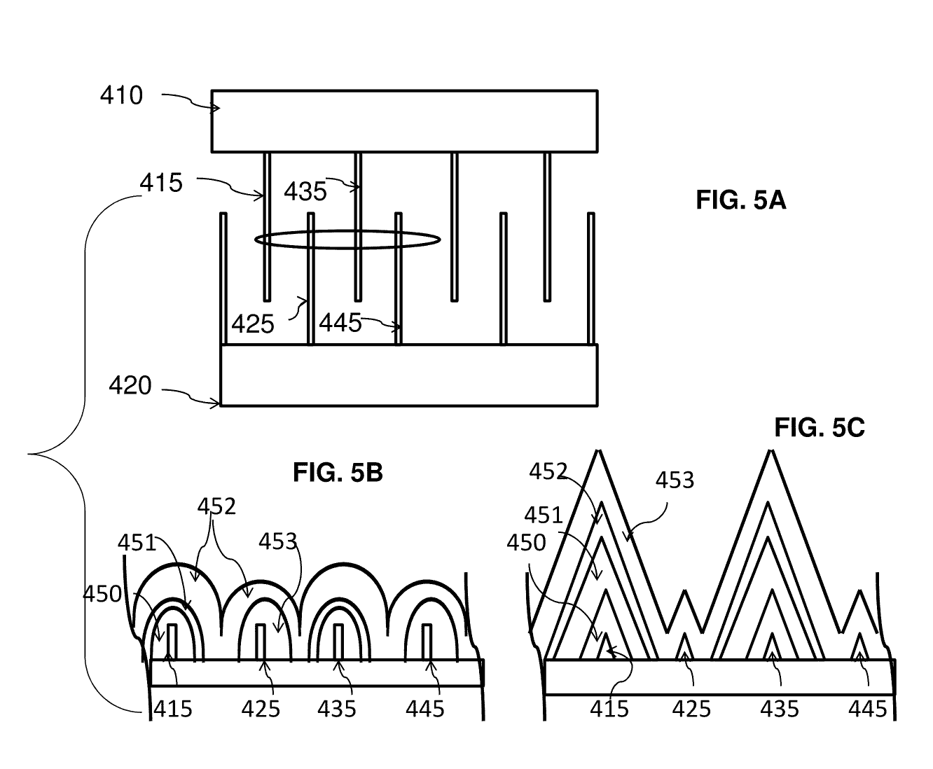

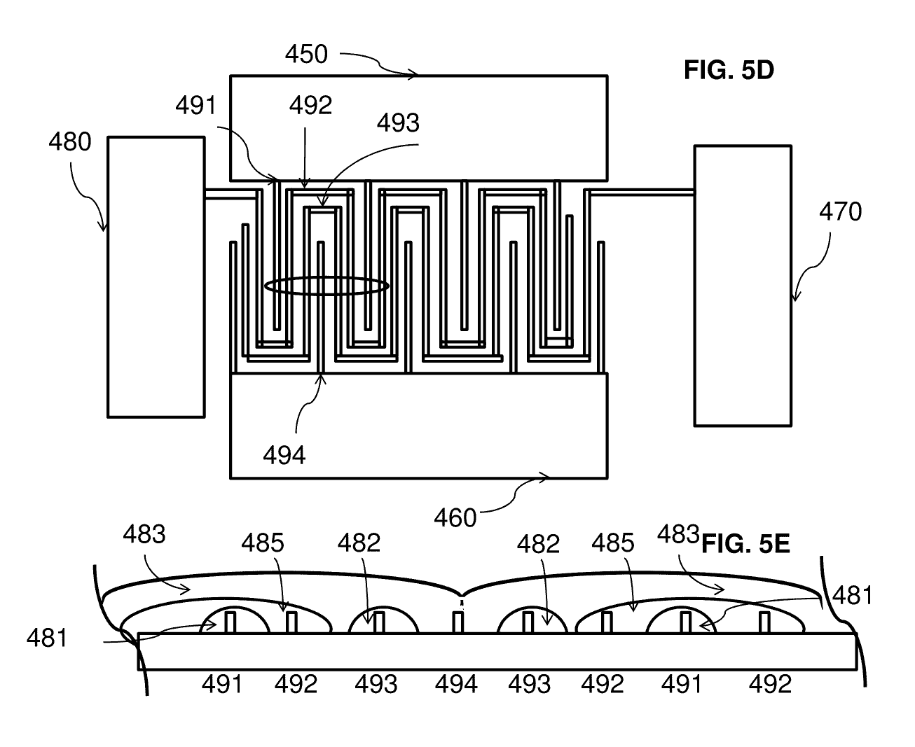

The process for electrodeposition on interdigitated electrodes could be used to create multijunction devices, in addition to homojunction and heterojunction devices. FIG. 5A is an interdigitated electrode structure for a multijunction photovoltaic device. The structure includes two interdigitated electrodes 410, 420 each containing a rectangular contact pad region and a number of electrode wires (lines), e.g., 415, 425, 435, 445 extending from a first pad toward a second pad in accordance with one embodiment of the present disclosure. The spacings between the electrode wires 415, 425, 435, 445 of FIG. 5 are not necessarily equal.

Referring now to FIG. 5B, illustrated are four adjacent interdigitated electrode wires from the interdigitated electrode device of FIG. 5A during semiconductor deposition of a multijunction photovoltaic device in accordance with one embodiment of the present disclosure. In this multijunction device, a first n-type material 450 could be deposited onto one electrode 410 including wires 415, 435 et al. using a first electrolyte. This deposit could be made without impingement of, i.e., without making contact with or without forming a bridge to, the deposit on the other electrode 420. Then, a first p-type material 451 could be deposited on the same electrode 410 including wires 415, 435 et al. and a second p-type material 453 could be deposited on the second electrode 420 including wires 425, 445 et al. in the same or different electrolytes, both without impingement of the deposits on the two electrodes 410, 420, the order being arbitrary. Finally a second n-type material 452 could be deposited onto one or both electrodes 410, 420 in the same or a different electrolyte or uniformly across the surface through any thin film deposition process. Deposition of the second n-type material 452 at least through impingement of the deposits on the two electrodes 410, 420 and use of semiconductors with appropriate bandgaps for the four materials 450, 451, 452, 453 could create an active device with the electrode1/n1/p1/n2/p2/electrode2 structure of a multijunction geometry. The same process could be accomplished with all occurrences of n-type replaced by p-type and all occurrences of p-type replaced by n-type. The first n-type material 450 and first p-type material 451 may have a smaller bandgap than the second n-type material 452 and second p-type material 453.

Referring now to FIG. 5C, illustrated is another embodiment of four adjacent interdigitated electrode wires from an interdigitated electrode device such as that of FIG. 5A, during semiconductor deposition of a multijunction photovoltaic device in accordance with one embodiment of the present disclosure. Shown in FIG. 5C are triangularly shaped electrode wires 415, 425, 435, 445, thus illustrating how the electrode wires may take on a shape other than the rectangular shape shown in FIG. 5B. Moreover, FIG. 5C shows how the shape of the electrodeposits and deposits may take on the shape of the electrode wire.

The photovoltaic device may include more than two electrodes. Referring now to FIG. 5D, illustrated is an interdigitated electrode structure for a multijunction device with four interdigitated electrodes 450, 460, 470, 480 each containing a rectangular contact pad region and a number of electrode wires (lines), e.g., 491, 492, 493, 494.

During semiconductor deposition, the multijunction device may be formed by depositing four materials 485, 481, 482, 483. Referring now to FIG. 5E, illustrated is an interdigitated electrode structure for a multijunction device with four interdigitated electrodes during semiconductor deposition in accordance with one embodiment of the present disclosure. On the wires shown in FIG. 5E, the first p-type material 481 is deposited onto electrode 450 including wire 491. A first n-type material 485 is deposited onto wires electrodes 450 and 480 including wires 491, 492. A second n-type material 482 is deposited onto electrode 470 including wire 493. A second p-type material 483 is deposited onto all electrodes including wires 491, 492, 493, 494.

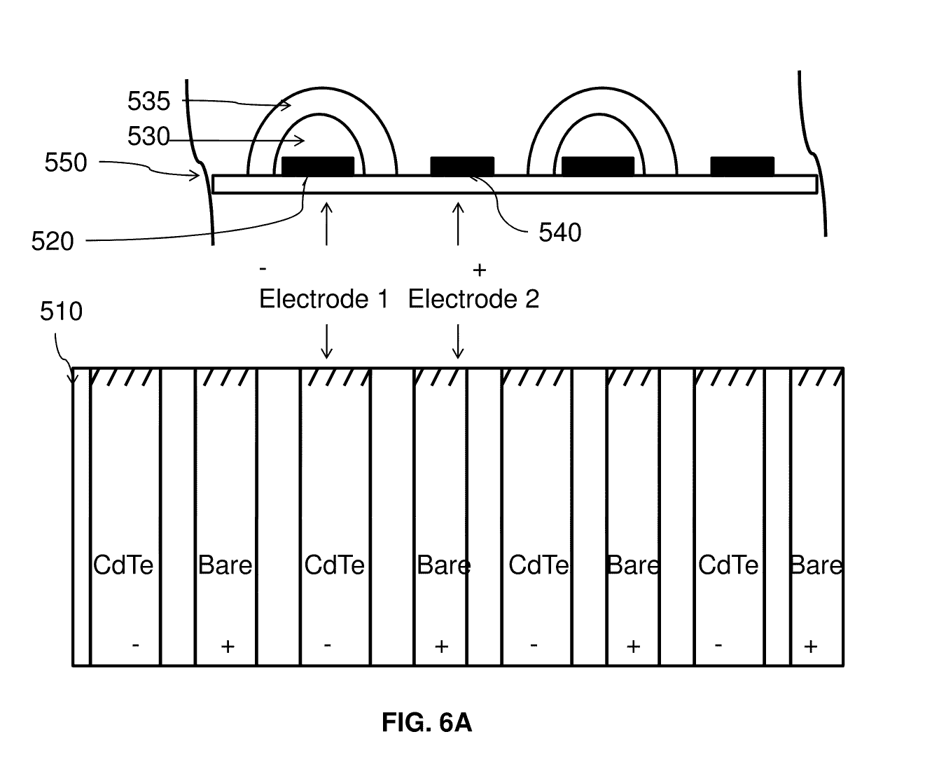

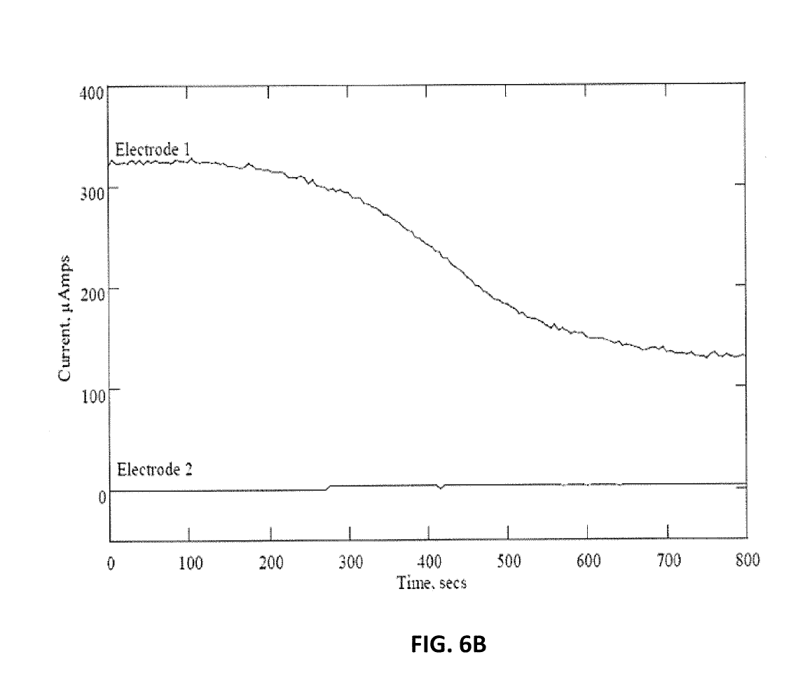

Referring now to FIG. 6A, illustrated is a specimen 510 with two interdigitated electrodes 520 and 540 after deposition of cadmium telluride material 530 on the alternating wires of one electrode 520 shown in a corresponding cross-sectional view 550. While the present illustration shows only four wires in the interdigitated electrodes of specimen 510, this number of wires is shown only for illustration of the concept. It should be understood that the specimen 510 could and may include hundreds and possibly even millions of wires.

During fabrication of the photovoltaic device, independent control of CdTe deposition on the electrodes 520 and 540 is demonstrated in this figure which illustrates a substrate 540 in planview after 15 minutes (min) of deposition with one gold (Au) electrode 510 held at −1.0 Vss and the other electrode 540 held at −0.2 Vss. One set of alternating wires in specimen 510 is wider (and thicker) due to CdTe deposition. Deposition is only evident on the electrode held at the more negative potential which falls within the range of conditions for CdTe codeposition.

Referring now to FIG. 6B, shown is a graphical illustration of the current histories on the electrodes of FIG. 6A. The current history in FIG. 6B exhibits a decrease of current indicating the transition from n-type material 530 to p-type material 535 and corresponding to fabrication of the geometry pictured in FIG. 6A. FIG. 6B also shows the breadth of the transition, which spans from roughly one-half to four-fifths of the total deposition charge, and may reflect variations in deposit thickness across the specimen. With this n-p junction, fabrication of a device requires only the additional deposition of p-type material on one or both electrodes at least until coalescence is achieved.

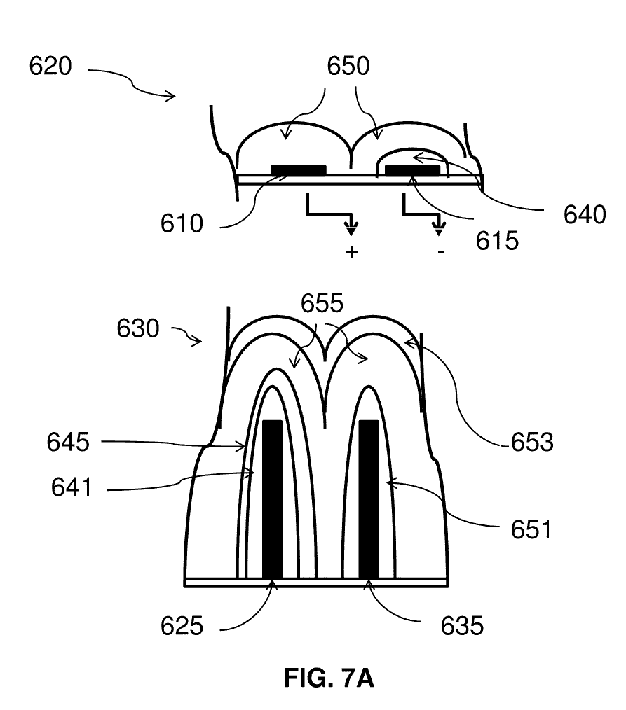

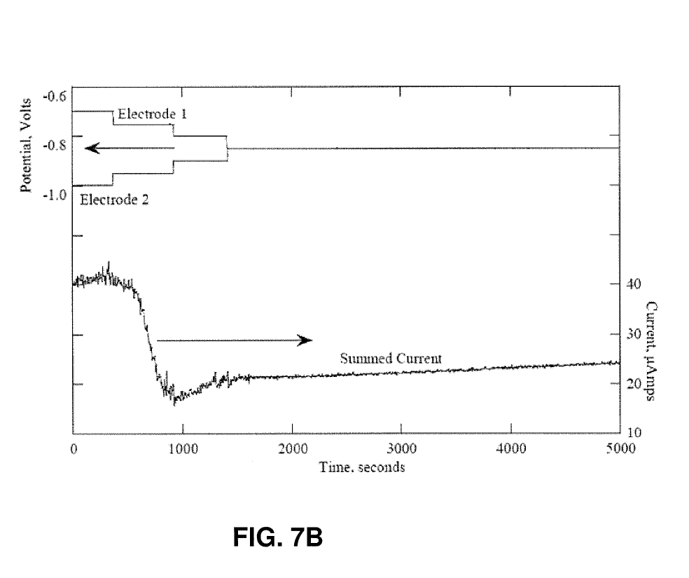

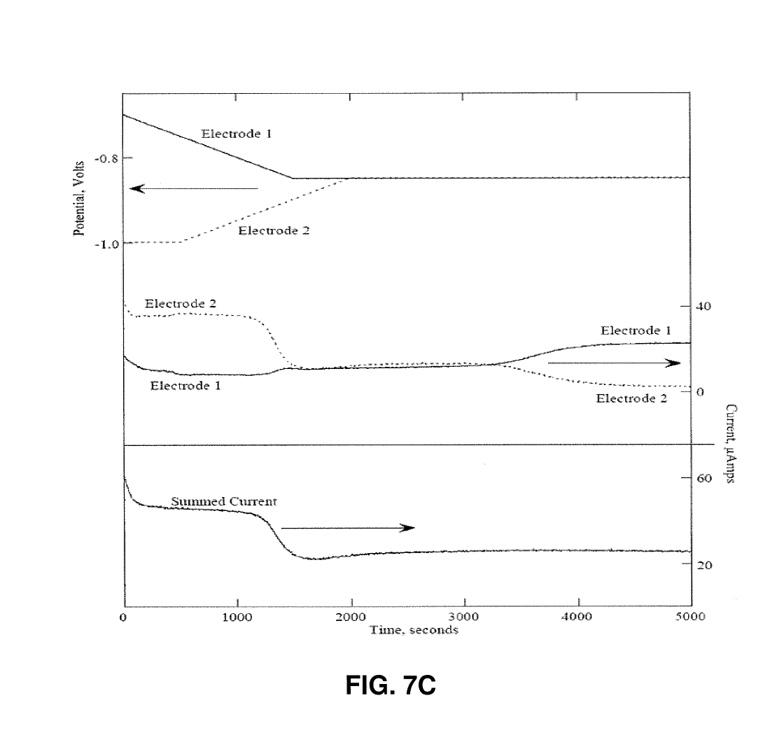

Referring now to FIG. 7A, illustrated are cross-section views of two adjacent interdigitated wires for devices with different aspect ratio wires in accordance with one embodiment of the present disclosure. The interdigitated wires 610, 615 of specimen 620 have deposited thereon both an n-type material 640 and p-type material 650. The interdigitated wires 625, 635 of specimen 630 also have an n-type material 645 and a p-type material 655. Specimen 630 also has higher aspect ratio wires, an additional n+ electrodeposited layer 641, and additional p+ type electrodeposited layer 651 and deposited layer 653 to improve device efficiency. More particularly, the n+ layer 641 bounces back the wrong sign charge carrier (holes) from wire 625; the p+ layer 651 bounces back the wrong sign charge carrier (electrons) from wire 635; and the p+ layer 653 bounces back one charge carrier (electrons) to reduce recombination at the device surface. Although two wires are shown in each of cross-sections 620, 630, it should be understood that the surfaces of the fabricated devices are composed of far larger numbers of interdigitated wires.

The electrodes of FIG. 7A (upper portion) may be wider, shorter, and of smaller cross-sectional area than desirable to minimize path length for a majority of carriers as compared to planar devices of equivalent (average) thickness. Decreased pitch and taller, narrower electrodes such as pictured in FIG. 7A bottom may be required to reduce carrier path lengths to dimensions defined by the lithography rather than the film thickness. Increased electrode height will, however, increase recombination at the metal/semiconductor interface. While these devices do not have an antireflection coating, surface texturing to improve device performance by bending light as it enters, increasing path length beyond the film thickness, is achieved as a direct result of the deposition process and initial geometry.

Referring now to FIG. 7B, illustrated are the histories of the voltages applied to the two electrodes and the sum of the currents measured over the first 5000 seconds of deposition on the two electrodes of an interdigitated electrode during fabrication of a device such as the device in FIG. 7A. The time at which the transition from n-type to p-type material occurs can be controlled by the potential history. The transition in the sum of the currents (summed current) on both electrodes manifests the n/p type transition. As shown in FIG. 7B, this transition occurs (on electrode 2) over the period from 500 to 1000 seconds while the potential is held at −0.95 Vss.

As per FIGS. 4 and 6B, the decrease in the summed current is associated with a decrease in the current on the more negative electrode. Smoothly varying deposition potential and possibly materials properties are also accessible through this process.

Referring now to FIG. 7C, shown is a graphical illustration of a potential history applied to the two electrodes to fabricate a device. The electrodes may be for either embodiment shown in FIG. 7A. The measured currents on the electrodes and the associated summed current for a specimen are shown where this potential history was applied to the two interdigitated electrodes during deposition. The diverging deposition currents for the electrodes in the last 1500 seconds of those 5000 seconds indicate the formation of electrical contact between the deposits on the two electrodes through impingement of the deposits on the two electrodes. Current flow to the deposit surface may be greater from the electrode that is not surrounded by the n-p junction after formation of such electrical contact.

The contact metallizations for the n-type and p-type semiconductors may be differentiated through the deposition of 90 nm of indium (In) onto one electrode prior to CdTe deposition. Indium deposition may be conducted in an indium-sulfate containing electrolyte of pH 2 obtained through additions of sulfuric acid to 18MΩcm water: electrode potentials were −1.0 V and −0.1 V for the plated and unplated electrodes, respectively. An intermediate dip between the In and CdTe depositions in 18 MΩcm water of pH 2 (also through addition of sulfuric acid) may be used to minimize cross-contamination between the In and CdTe. The more negative potential may be applied to the same electrode for both the In and CdTe depositions, placing the n-type CdTe over the In.

The photovoltaic devices that resulted from the process using electrodeposition on interdigitated electrodes showed systematic variations in performance. In interpreting device performance, the planar films on both Au and Ir were considered both as-deposited and after annealing. Energy dispersive x-ray spectroscopy measurements obtained from scanning electron microscope (SEM) images of planar deposits indicate the thin film specimens are essentially-stoichiometric CdTe. Measurements conducted on individual wires of a device with intermediate pitch Au electrodes (deposition parameters detailed in Table I) also indicate near-stoichiometric CdTe on both electrodes. Annealing of CdTe on Au substrates led to substantial interdiffusion of the Au and CdTe. This could eliminate the incorporated p-n junction on the patterned specimens with Au electrodes and other materials, monolithic or composite, may be considered as more thermally stable or otherwise more desirable electrodes.

The dielectric function for as-deposited and annealed (at 300° C. for 20 minutes) planar CdTe films was determined by variable angle spectroscopic ellipsometry. A multisample analysis was performed with two films deposited for 30 min and 60 min in the primary electrolyte at −0.8 V and 50° C. and specimen rotation rate of 60 rpm with resulting film thicknesses of approximately 120 nm and 230 nm.

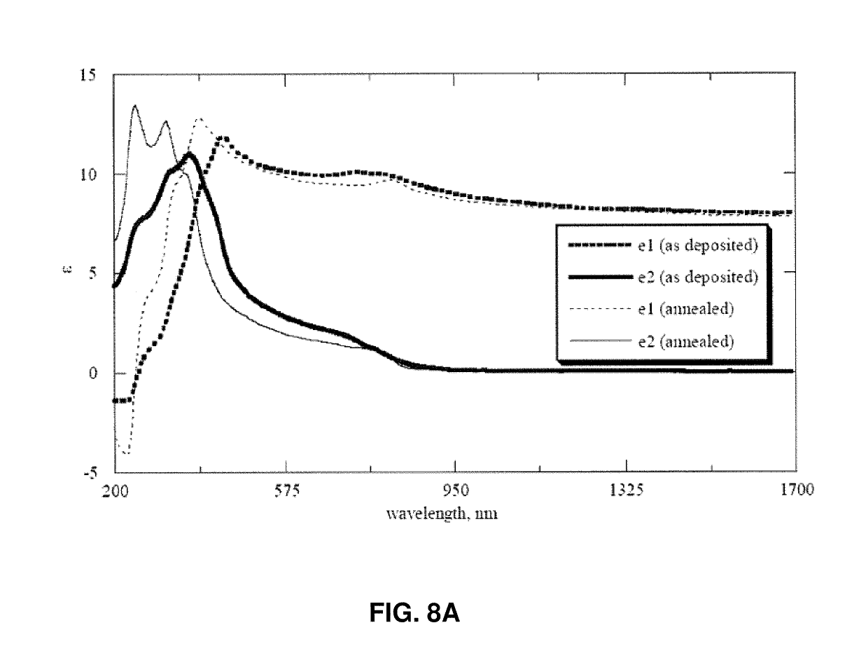

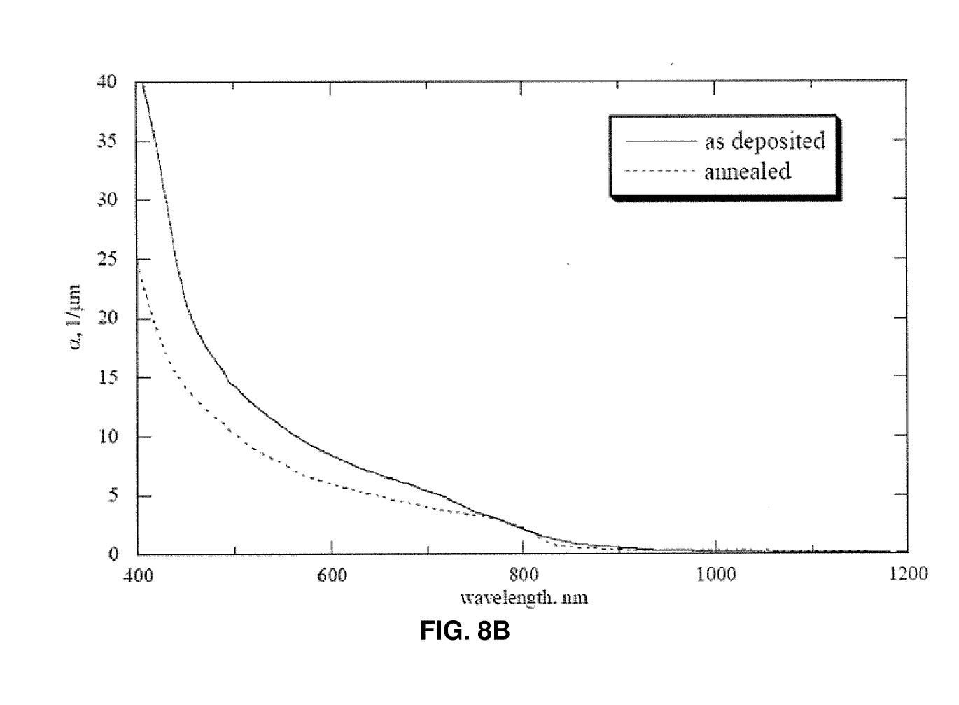

The dielectric function for the CdTe bulk was determined by a wavelength fit of the imaginary part of the dielectric function ∈=∈₁∈₂ with the real part ∈₁ derived from a Kramers-Kronig transform based on the numerical integration of ∈₂. Referring now to FIG. 8A, shown is a graphical illustration of the real and imaginary parts of the dielectric function ∈ for cadmium telluride deposited on iridium substrates in both the as-deposited and annealed states in accordance with one embodiment of the present disclosure. FIG. 8A shows the derived ∈. The principle features of E for the annealed film are in good agreement with previously reported values for single crystal CdTe. Specifically, the direct gap at approximately 825 nm (≈1.50 eV), along with the E₁ (373 nm). E1+Δ₁ (320 nm), and E2 (245 nm) critical points are clearly present. The crystalline spectral features are clearly broadened in the as-deposited film, indicative of disorder.

Referring now to FIG. 8B, shown is a graphical illustration of the derived absorption coefficient for as-deposited and annealed cadmium telluride in accordance with one embodiment of the present disclosure. FIG. 8B shows the absorption coefficient derived from ∈, in the region of the direct gap. The poor microstructure of the as-deposited film is reflected in the evidence for tail states at wavelengths greater than the gap value and increased absorption at wavelengths shorter than the gap value.

X-ray diffraction results for CdTe films studied in a θ-2θ geometry exhibit narrowing and a shift of the diffraction peaks of the as-deposited CdTe upon annealing. The narrowing in particular is consistent with the material improvements suggested by the ellipsometric data.

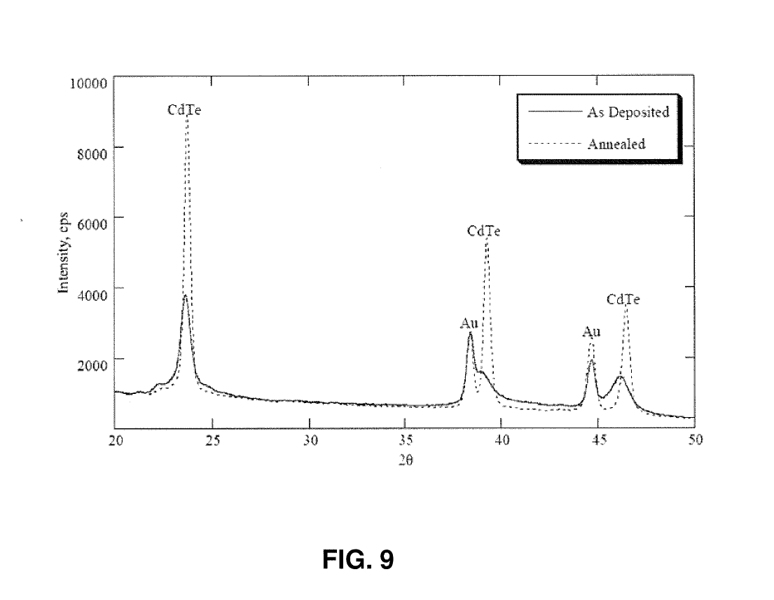

Referring now to FIG. 9, shown is a graphical illustration of X-ray diffraction results for two cadmium telluride deposits in accordance with one embodiment of the present disclosure. FIG. 9 shows data for planar as-deposited and annealed CdTe films deposited at −0.8 V. In this case, the electrolyte contained 0.1 μmol/L to 0.2 μmol/L CuSO₄ for Cu p-type doping.

Measurements were taken for the photovoltaic devices that were fabricated through electrodeposition on interdigitated electrodes. Performance of these photovoltaic devices was measured in terms of external quantum efficiency (EQE). EQE may be defined as the ratio of the number of charge carriers collected by the photovoltaic to the number of photons of a given energy shining on the photovoltaic device from outside.

When sunlight illuminates a photovoltaic device, the photons of light are absorbed by the semiconductor(s) of the photovoltaic device. Negatively charged electrons are moved from the valence band of the semiconductor(s) into the conduction band. Contact between thin layers of n-type and p-type semiconductors and their respective contact with different electrodes encourages motion of the negatively charged electrons and positively charged holes toward different electrodes. The photovoltaic device thus converts the solar energy into usable electricity.

In the fabricated devices, charge carrier extraction is accomplished by the same electrodes that were used for device fabrication. Electrons and holes are extracted at different electrodes.

External quantum efficiencies (EQE) in the range of 300 nm to 1100 nm were determined by illumination of a 2 mm diameter region toward the center of the fabricated devices. The spectral response SR(λ), in amps/watt, was obtained from the ratio of the sample photocurrent to that of a NIST-traceable, calibrated Si photo diode under equivalent lighting, multiplied by the known response, in amps/watt, of the photodiode. External quantum efficiencies as a function of wavelength were then calculated using EQE=(hc/qλ)SR(λ), where h is Planck's constant, c is the speed of light in vacuum, q is the elementary charge and λ is the wavelength.

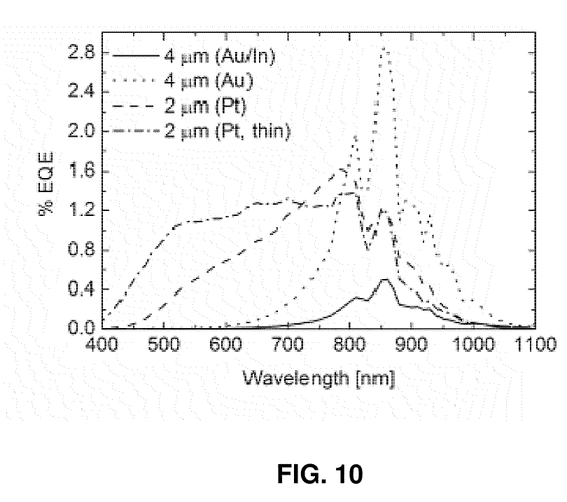

Referring now to FIG. 10, shown is a graphical illustration of the efficiency of the conversion of light energy to electrical energy as a function of the wavelength of the incoming light for as-deposited devices in accordance with one embodiment of the present disclosure. EQEs of four as-deposited CdTe homojunction devices are shown in FIG. 10. Details of the electrode geometry and materials as well as CdTe deposition processes for the four specimens are given in Table 1 below.

TABLE 1

| | | | | | | CdTe on | |
|---|---|---|---|---|---|---|---|
| | | | | | | electrode, | |
| | Electrode | | Electrode 1 | Electrode 2 | Deposition | μm | |
| Pitch | 1 | 2 | History, V₁(t) | Voltage, V₂(t) | time, hrs | 1 | 2 |
| 4 μm | Au | Au | −0.7 V, 500 s | −1.0 V, 500 s | 4 | 1.2 | 1.2 |
| | | | −0.75 V, 500 s | −0.95 V, 500 s | | | |
| | | | −0.8 V, 500 s | −0.9 V, 500 s | | | |
| | | | −0.85 V, hold | −0.85 V, hold | | | |
| 4 μm | In on | Au | −0.7 V, 500 s | −1.0 V, hold | 4 | 1.2 | 1.2 |
| | Au | | −0.75 V, 500 s | | | | |
| | | | −0.8 V, 500 s | | | | |
| | | | −0.85 V, hold | | | | |
| 2 μm | Pt | Pt | −0.7→−0.85 V, 1500 | −1.0 V, 500 s | 2 | 0.5 | 0.7 |
| | | | −0.85 V, hold | −1.0→−0.85 V, 1500 s | | | |
| | | | | −0.85 V, hold | | | |
| 2 μm | Pt | Pt | −0.8→−0.85 V, 1500 | −1.0 V, 500 s | 1¼ | 0.3 | 0.5 |
| | | | −0.85 V, hold | −1.0→−0.85 V, 1500 s | | | |
| | | | | −0.85 V, hold | | | |

Data for the first 5000 seconds of CdTe deposition on the intermediate pitch device with two Au electrodes is shown in FIG. 7B. The first 5000 seconds of deposition data for the fine pitch device with 2 hours CdTe deposition is shown in FIG. 7C.

As determined by cross-section examination, and indicated in Table I, the different deposition rates in the earlier times of the 5000 seconds resulted in different CdTe thicknesses on the two electrodes of the two fine pitch devices.

Unsurprisingly, all four devices exhibit low efficiencies in the as-deposited state, although the devices with thinner CdTe exhibit broader spectral responses. The low values may be due to the fact that electrodeposited CdTe is typically annealed, often in the presence of compounds such as CdCl₂, to improve its properties. Because there was a substantial variation in the maximum efficiencies of intermediate pitch specimens as a function of position on the device, the maximum values of efficiencies for the specimens are not deemed to be significant. Also, because no antireflection coating was used, the front surface reflectivity of the films represents a significant loss.

The optical response of a back contact photovoltaic cell is a complex interplay between the optical characteristics of the film and the electrical characteristics. The film properties determine the absorption depth and front surface reflectivity. Electrical characteristics include interface recombination velocities and minority carrier diffusion lengths. However, the gross characteristics of the EQE curves in FIG. 10 can be reconciled with the optical properties of the as-deposited material shown in FIG. 8A and its known disorder. For the devices fabricated on 4 μm pitch interdigitated electrodes, the significant optical response at wavelengths longer than the nominal CdTe gap of 828 nm may reflect the significant tail states in the disordered material. The sharp drop in response at shorter wavelengths may arise from poor minority carrier diffusion lengths that prohibit the carriers generated at the top of the thick film from reaching the buried junctions.

Such interpretations would be consistent with earlier reports of efficiency in electrochemically deposited planar devices. These reports show that EQE peaks at less than 10% and 2% for 1 μm thick CdTe electrodeposited on CdS at potentials 125 mV and 250 mV more positive than the Cd reversible potential, respectively. For the measured Cd reversible potential of approximately −1.07 Vss, the potential histories summarized in Table I involve values as much as 350 mV positive of the Cd reversible value, and the majority of deposition is between 100 mV and 200 mV positive, even without correcting for resistive voltage drop through the films during deposition.

The efficiencies and general spectral responses in FIG. 10 are consistent with published results for planar CdTe deposited at similar potentials on CdS and studied in a liquid cell. Confirmation of limited short wavelength response due to poor carrier diffusion is provided by the improved blue performance of the finer pitch, thinner film devices. The fine structure in the EQE, particularly pronounced in the 4 μm pitch devices, may be attributed to light trapping effects due to scattering from the grating pitch into guided modes of the thin film.

Because improved microstructure was observed through spectroscopic ellipsometry and X-ray diffraction upon annealing, one could anticipate significant improvement in device performance following thermal treatment. For the homojunction devices fabricated, the benefits of microstructural changes obtained through annealing may be offset by type-conversion of part or all of the deposit as well as diffusion from the gold contacts, where applicable. Deposition of different material(s) on one or both of the electrodes might enable improvement through annealing by differential doping around the contacts as well as improve the electrical properties of the contacts. The contact(s) may also be capped with conducting oxide or nitride (or such a coating may be grown through reaction of the contact) to decrease recombination and/or act as a diffusion barrier if their presence does not degrade the deposition process.

In accordance with the present disclosure, both homojunction and heterojunction photovoltaic devices may be created through electrodeposition on interdigitated electrodes. Such photovoltaic devices can take many forms. However, all of these devices share a common attribute: the interdigitated electrodes may be used both for deposition of one or more semiconductors and as backside contacts for carrier collection from the photovoltaic devices.

The versatility of the electrodeposition process and back contact geometry is evident, including control of materials properties through applied potential in one or more electrolytes.

As described herein, a single lithographic patterning procedure for fabricating micrometer scale, interdigitated back contact devices may be extrapolated from demonstrated CdTe homojunction devices to heterojunction-based devices containing a broad range of materials. The use of lithography to define the geometry also enables a systematic transition from second-generation planar, thin film with contact geometries to third generation geometries with nanostructuring.

While the specification describes particular embodiments of the present invention, those of ordinary skill can devise variations of the present invention without departing from the inventive concept.

We claim:

1. An electrodeposition method for forming a three dimensionally structured thin film photovoltaic device with self-aligned back contacts, comprising the steps of:
fabricating a photovoltaic device, including the steps of:
providing at least two interdigitated electrodes on an insulating substrate, each of the at least two interdigitated electrodes including a plurality of interdigitated wires having pitches of less than ten micrometers; in a first step, electrodepositing one or more thin films of one or more of a first semiconducting material onto a first interdigitated electrode, wherein the first semiconducting material is one of an n-type or p-type material;
in a second step, depositing one or more thin films of one or more of a second semiconducting material onto at least a second interdigitated electrode until the deposits on the first interdigitated electrode and the second interdigitated electrode impinge upon each other, wherein the second semiconducting material is the other of an n-type or p-type material; and
wherein, after fabrication of the photovoltaic device, at least two of said at least two interdigitated electrodes serve as the back contacts for carrier extraction when the device is in use.

2. The method of claim 1, further comprising:
prior to the first step, electrodepositing thin films of one or more non-semiconducting materials onto one or more of the at least two interdigitated electrodes;

3. The method of claim 1, wherein the p-type materials are selected from the group consisting of cadmium telluride, copper indium diselenide, copper indium gallium diselenide and copper oxide, and wherein said materials are doped or undoped.

4. The method of claim 1, wherein the n-type materials are either cadmium sulfide or zinc oxide, and wherein said materials are doped or undoped.

5. The method of claim 1, wherein the insulating substrate is planar or patterned.

6. The method of claim 1, wherein the first step of electrodepositing includes the step of masking the substrate surface.

7. The method of claim 1, wherein the second step of depositing includes one or more of electrodeposition, chemical vapor deposition, chemical bath deposition, sputtering, physical vapor deposition, evaporation, spray coating, spin coating, dip coating, flow coating, ink jetting, plasma spraying and laser ablation.

8. The method of claim 1, wherein the first step of electrodepositing or second step of depositing includes the step of:
rotating the substrate on a rotating substrate holder, the holder being adapted to hold the substrate.

9. The method of claim 1, further comprising the step of:
applying potentials to the interdigitated electrodes such that an n-type to p-type or p-type to n-type transition occurs on one electrode prior to impingement of the deposits so that a homojunction photovoltaic device is formed upon impingement.

10. The method of claim 1, wherein the first step of electrodepositing and the second step of depositing occur simultaneously in a single electrolyte such that at least two different materials deposit on the first and second interdigitated electrodes, and a heterojunction photovoltaic device is formed.

11. The method of claim 1, wherein the n-type and p-type materials are dissimilar materials; and
wherein the first step of electrodepositing occurs in at least a first electrolyte; and
wherein the second step of depositing occurs in at least a second electrolyte such that a heterojunction photovoltaic device is formed.

12. The method of claim 11, further comprising:
in a third or subsequent step, depositing a thin film of material onto both electrodes.

13. An electrodeposition method for forming a multijunction three dimensionally structured thin film photovoltaic device with self-aligned back contacts, comprising the steps of:
fabricating a multijunction photovoltaic device, including the steps of:
providing at least two interdigitated electrodes on an insulating substrate, each of the at least two interdigitated electrodes including a plurality of interdigitated wires having pitches of less than ten micrometers, wherein the at least two interdigitated electrodes include a first interdigitated electrode and a second electrode; in a first step, electrodepositing one or more thin films of one or more of a first semiconducting material onto the first interdigitated electrode without impingement upon any other of the at least two interdigitated electrode, the first semiconducting material being one of an n-type or p-type material
in a second step, electrodepositing one or more thin films of one or more of a second semiconducting material onto at least said first interdigitated electrode but without impinging upon said second interdigitated electrode, the second semiconducting material being the other type of an n-type or p-type material;
in a third step, electrodepositing one or more thin films of one or more of a third semiconducting material onto either the first or second interdigitated electrode without impinging on the other of the first or second interdigitated electrode, the third semiconducting material being either the same type as the first type if electrodeposited on the first interdigitated electrode, or the same type as the second semiconducting material if electrodeposited on the second interdigitated electrode, wherein the third semiconducting material is either an n-type or p-type material;
in a fourth step, depositing one or more thin films of one or more of a fourth semiconducting material onto one or more of the at least two interdigitated electrodes, wherein the depositing occurs at least until the thin films on the first interdigitated electrode and the second interdigitated electrodes impinge upon each other, wherein the fourth semiconducting material is the other of said either an n-type or p-type material electrodeposited in the third step; and
wherein, after fabrication of the multijunction photovoltaic device, at least two of said at least two interdigitated electrodes serve as the back contacts for carrier extraction when the device is in use.

14. The method of claim 13, wherein:
prior to the first step, electrodepositing thin films of one or more non-semiconducting materials onto one or more of the electrodes.

15. A three dimensionally structured thin film photovoltaic device with self-aligned back contacts formed by electrodeposition on interdigitated electrodes used in the device's manufacture, comprising:
an insulating substrate;
at least two interdigitated electrodes on the insulating substrate, the at least two interdigitated electrodes including a plurality of interdigitated wires having pitches of less than ten micrometers, wherein the at least two interdigitated electrodes include a first interdigitated electrode and a second interdigitated electrode;
one or more electrodeposited thin film layers of one or more of a first semiconducting material on the first interdigitated electrode, wherein the first type is either an n-type or p-type material;
one or more deposited thin film layers of one or more of a second semiconducting material on the second interdigitated electrode, wherein the deposits on the first interdigitated electrode and the second interdigitated electrode impinge upon each other, wherein the second semiconducting material is the other of an n-type or p-type material; and
wherein, after fabrication, at least two of said at least two interdigitated electrodes are configured to serve as the back contacts for carrier extraction, when the device is in use.

16. The device of claim 15, further comprising:
beneath the one or electrodeposited thin film layers of a first semiconducting material, an electrodeposited thin film layer of one or more non-semiconducting materials on one or more of the electrodes.

17. The device of claim 15, wherein the p-type material is selected from the group consisting of: cadmium telluride, copper indium diselenide, copper indium gallium diselenide and copper oxide, and wherein the p-type material is doped or undoped.

18. The device of claim 15, wherein the n-type material is either cadmium sulfide or zinc oxide, and wherein the n-type material is doped or undoped.

19. The device of claim 15, wherein the insulating substrate is planar or patterned.

20. The device of claim 15, wherein the one or more deposited thin film layers are formed by at least one of electrodeposition, chemical vapor deposition, chemical bath deposition, sputtering, physical vapor deposition, evaporation, spray coating, spin coating, dip coating, flow coating, ink jetting, plasma spraying, and laser ablation.

21. A three dimensionally structured thin film multijunction photovoltaic device with self-aligned back contacts formed by electrodeposition on interdigitated electrodes used in the device's manufacture, comprising:
an insulating substrate;
at least two interdigitated electrodes on the insulating substrate, the at least two interdigitated electrodes including a plurality of interdigitated wires having pitches of less than ten micrometers, wherein the at least two interdigitated electrodes include a first interdigitated electrode and a second interdigitated electrode; one or more electrodeposited thin film layers of one or more of a first semiconducting material on the first interdigitated electrode without impingement upon any of the other interdigitated electrodes, wherein the first semiconducting material is one of an n-type or p-type material;
one or more electrodeposited thin film layers of one or more of a second semiconducting material onto at least said first interdigitated electrode but without impinging upon the second interdigitated electrode, wherein the second semiconducting material is the other of an n-type or p-type material;
one or more electrodeposited thin film layers of one or more of a third semiconducting material on either the first or second interdigitated electrode without impinging upon the first and second interdigitated electrodes, the third type being either the same type as the first type if electrodeposited on the first interdigitated electrode or the same type as the second type if electrodeposited on the second interdigitated electrode, wherein the third semiconducting material is either an n-type material or a p-type material;
one or more deposited layers of one or more of a fourth semiconducting material on one or more of the interdigitated electrodes such that the deposits on at least the first interdigitated electrode and the second interdigitated electrodes impinge upon each other, and wherein the fourth semiconducting material is the other of said either an n-type or p-type material as the third material; and
wherein, after fabrication, at least two of said at least two interdigitated electrodes are configured to serve as the back contacts for carrier extraction when the device is in use.

22. The device of claim 21, further comprising:
beneath the one or electrodeposited thin film layers of a first semiconducting material, an electrodeposited thin film layer of one or more non-semiconducting materials on one or more of the electrodes.

23. The device of claim 21, wherein the p-type material is selected from the group consisting of: cadmium telluride, copper indium diselenide, copper indium gallium diselenide and copper oxide, wherein the p-type material is doped or undoped.

24. The method of claim 21, wherein the n-type material is either cadmium sulfide or zinc oxide, wherein the n-type material is doped or undoped.

25. The device of claim 21, wherein the insulating substrate is planar or patterned.

26. The device of claim 21, wherein the deposited layer was formed by at least one of electrodeposition, chemical vapor deposition, chemical bath deposition, sputtering, physical vapor deposition, evaporation, spray coating, spin coating, dip coating, flow coating, ink jetting, plasma spraying, and laser ablation.
